(19) United States
(12) Patent Application Publication
(10) Pub. No.: US 2007/0251446 A1
(43) Pub. Date: Nov. 1, 2007

(54) Chemically attached diamondoids for CVD diamond film nucleation

(75) Inventors: Jeremy E. Dahl, Palo Alto, CA (US); Robert M. Carlson, Petaluma, CA (US); Wasiq Bokhari, Menlo Park, CA (US); Shenggao Liu, Hercules, CA (US)

Correspondence Address: BUCHANAN, INGERSOLL & ROONEY PC, POST OFFICE BOX 1404, ALEXANDRIA, VA, 22313-1404, US

(73) Assignee: Chevron U.S.A. Inc., San Ramon, CA (US)

(21) Appl. No.: 11/725,465

(22) Filed: Mar. 20, 2007

Related U.S. Application Data
(60) Provisional application No. 60/785,375, filed on Mar. 24, 2006.

(51) Int. Cl. C30B 23/00

(52) U.S. Cl. 117/104; 117/84

(57) ABSTRACT

Provided is a novel method for nucleating the growth of a diamond film. The method comprises providing a substrate having a diamondoid chemically attached to it, which serves as a superior nucleation site, and then facilitating the growth of the diamond film.

This application claims priority to U.S. Provisional Application No. 60/785,375 filed Mar. 24, 2006, which is herein incorporated by reference in its entirety.

### FIELD OF THE INVENTION

Disclosed is an improved method of nucleating the growth of a diamond film. The present invention also relates to new application for such diamond films.

### BACKGROUND OF THE INVENTION

Diamondoids are available in a wide variety of shapes and sizes. Diamondoids are bridged-ring cycloalkanes. Lower diamondoids, adamantane, diamantane and triamantane, are composed of 1, 2 and 3 diamond crystal cages respectively. Recently discovered higher diamondoids, from tetramantane to undecamantane, are made up of from 4 to 11 diamond crystal cages. Such higher diamondiods are described in U.S. Pat. Nos. 6,815,569; 6,843,851; 6,812,370; 6,828,469; 6,831,202; 6,812,371; 6,844,477; and 6,743,290, which patents are herein incorporated by reference in their entirety.

Attempts to synthesize diamond films using chemical vapor deposition (CVD) techniques date back to before the 1980's. An outcome of these efforts was the appearance of new forms of carbon largely amorphous in nature, yet containing a high degree of sp³-hybridized bonds, and thus displaying many of the characteristics of diamond. To describe such films the term “diamond-like carbon” (DLC) was coined, although this term has no precise definition in the literature. In “The Wonderful World of Carbon,” Prawer teaches that since most diamond-like materials display a mixture of bonding types, the proportion of carbon atoms which are four-fold coordinated (or Sp³-hybridized) is a measure of the “diamond-like” content of the material. Successful CVD diamond film creation is described in U.S. Pat. No. 6,783,589, which is herein incorporated by reference in its entirety. Other publications which discuss diamond film growth include Spitsyn, B. V., “Nucleation of diamond from vapor phase and synthesis of nanostructured diamond films,” NATO Science Series, II: Mathematics, Physics and Chemistry 155 (Nanostructured Thin Films and Nanodispersion Strengthened Coatings), 123-136 (2004); Soga, T.; Sharda, T.; Jimbo, T., “Precursors for CVD growth of nanocrystalline diamond,” Physics of the Solid State (Translation of Fizika Tverdogo Tela (Sankt-Peterburg), 46(4), 720-725 (2004); Jager, W.; Jiang, X., “Diamond heteroepitaxy-nucleation, interface structure, film growth,” Acta Metallurgica Sinica (English Letters) 14(6), 425-434 (2004); Jiang, X., “Textured and heteroepitaxial CVD diamond films,” Semiconductors and Semimetals 76 (Thin-Film Diamond I), 1-47(2003); Iijima, S., Aikawa, Y. & Baba K. “Growth of diamond particles in chemical vapor deposition,” J Mater Res. 6,1491-1497 (1991); Philip J., Hess, P, Feygelson T., Butler J. E., Chattopadhyay S., Chen K. H., and Chen L. C, “Elastic, mechanical, and thermal properties of nanocrystalline diamond films,” Journal of Appl. Physics V. 93#3 (2003).

The potential of diamond-like materials in microelectronics and other applications is unlimited. While excellent methods of CVD diamond creation do exist, further improvements are always needed. Previous nucleation methods are limited in that they can only generate polycrystalline diamond films. Polycrystalline films are of limited use, especially for electronics application, in that diamond crystallites exhibit various orientations with respect to their internal lattice framework, and are separated by non-diamond grain boundaries. Furthermore, previous methods show limited nucleation densities which can produce limited surface coverage and rough surfaces resulting from large crystallite formation.

### SUMMARY OF THE INVENTION

Chemically attaching diamondoids to the desired substrate prior to CVD deposition provide the potential to significantly enhance the process of CVD diamond creation as well as to enable new applications for CVD diamond structures. There are multiple ways in which diamondoids can uniquely contribute.

It has been discovered that there are many advantages to chemically attaching diamondoids to substrates prior to deposition. These include: (1) maximum seeding densities producing smaller crystallites size reducing surface roughness; (2) mitigation of delamination problems with concomitant improvement in heat transfer characteristics; (3) no surface abrasion of the substrate; (4) the ability to pattern CVD growth; (5) enhancement of CVD growth of particular diamond crystal faces allowing homoepitaxial growth greatly improving diamond film properties making possible new electronics applications; (6) ability to select the precise size of nucleation seeds; (7) growth of doped diamond; (8) coating of non-conducting substrates; and (9) use of irradiation. All of the foregoing advantages are realized in the practice of the present invention, which provides a novel method of nucleating the growth of a diamond film, with the substrate upon which the film is grown having chemically attached to it a diamondoid prior to nucleation.

### BRIEF DESCRIPTION OF THE FIGURES OF THE DRAWINGS

FIG. 1 shows a CVD diamond crystalline film formed using diamondoid seed crystals.

FIG. 2 shows a diamondoid molecule bound to a surface acting as an oriented seed crystal.

FIG. 3 shows a diamondoid bonded to a metal surface.

FIGS. 4A, B and C show diamondoids attached to a silicon surface through a silyl ether bond.

FIGS. 5A, B and C show how decamantane molecules can be attached to a silicon surface.

FIG. 6 shows a reactor to sublime diamondoids into the gas phase for CVD.

### DETAILED DESCRIPTION OF THE PREFERRED EMBODIMENTS

### Definition of Diamondoids

The term “diamondoids” refers to substituted and unsubstituted caged compounds of the adamantane series including adamantane, diamantane, triamantane, tetramantane, pentamantane, hexamantane, heptamantane, octamantane, nonamantane, decamantane, undecamantane, and the like, including all isomers and stereoisomers thereof. The compounds have a “diamondoid” topology, which means their carbon atom arrangement is superimposable on a fragment of an FCC diamond lattice. Substituted diamondoids comprise from 1 to 10 and preferably 1 to 4 independently-selected alkyl substituents. Diamondoids include “lower diamondoids” and “higher diamondoids,” as these terms are defined herein, as well as mixtures of any combination of lower and higher diamondoids.

The term “lower diamondoids” refers to adamantane, diamantane and triamantane and any and/or all unsubstituted and substituted derivatives of adamantane, diamantane and triamantane. These lower diamondoid components show no isomers or chirality and are readily synthesized, distinguishing them from “higher diamondoids.”

The term “higher diamondoids” refers to any and/or all substituted and unsubstituted tetramantane components; to any and/or all substituted and unsubstituted pentamantane components; to any and/or all substituted and unsubstituted hexamantane components; to any and/or all substituted and unsubstituted heptamantane components; to any and/or all substituted and unsubstituted octamantane components; to any and/or all substituted and unsubstituted nonamantane components; to any and/or all substituted and unsubstituted decamantane components; to any and/or all substituted and unsubstituted undecamantane components; as well as mixtures of the above and isomers and stereoisomers of tetramantane, pentamantane, hexamantane, heptamantane, octamantane, nonamantane, decamantane, and undecamantane.

Isolation of Diamondoids from Petroleum Feedstocks

Feedstocks that contain recoverable amounts of higher diamondoids include, for example, natural gas condensates and refinery streams resulting from cracking, distillation, coking processes, and the like. Particularly preferred feedstocks originate from the Norphlet Formation in the Gulf of Mexico and the LeDuc Formation in Canada.

These feedstocks contain large proportions of lower diamondoids (often as much as about two thirds) and lower but significant amounts of higher diamondoids (often as much as about 0.3 to 0.5 percent by weight). The processing of such feedstocks to remove non-diamondoids and to separate higher and lower diamondoids (if desired) can be carried out using, by way of example only, size separation techniques such as membranes, molecular sieves, etc., evaporation and thermal separators either under normal or reduced pressures, extractors, electrostatic separators, crystallization, chromatography, well head separators, and the like.

A preferred separation method typically includes distillation of the feedstock. This can remove low-boiling, non-diamondoid components. It can also remove or separate out lower and higher diamondoid components having a boiling point less than that of the higher diamondoid(s) selected for isolation. In either instance, the lower cuts will be enriched in lower diamondoids and low boiling point non-diamondoid materials. Distillation can be operated to provide several cuts in the temperature range of interest to provide the initial isolation of the identified higher diamondoid. The cuts, which are enriched in higher diamondoids or the diamondoid of interest, are retained and may require further purification. Other methods for the removal of contaminants and further purification of an enriched diamondoid fraction can additionally include the following nonlimiting examples: size separation techniques, evaporation either under normal or reduced pressure, sublimation, crystallization, chromatography, well head separators, flash distillation, fixed and fluid bed reactors, reduced pressure, and the like.

The removal of non-diamondoids may also include a pyrolysis step either prior or subsequent to distillation. Pyrolysis is an effective method to remove hydrocarbonaceous, non-diamondoid components from the feedstock. It is effected by heating the feedstock under vacuum conditions, or in an inert atmosphere, to a temperature of at least about 390° C., and most preferably to a temperature in the range of about 410 to 450° C. Pyrolysis is continued for a sufficient length of time, and at a sufficiently high temperature, to thermally degrade at least about 10 percent by weight of the non-diamondoid components that were in the feed material prior to pyrolysis. More preferably at least about 50 percent by weight, and even more preferably at least 90 percent by weight of the non-diamondoids are thermally degraded.

While pyrolysis is preferred in one embodiment, it is not always necessary to facilitate the recovery, isolation or purification of diamondoids. Other separation methods may allow for the concentration of diamondoids to be sufficiently high given certain feedstocks such that direct purification methods such as chromatography including preparative gas chromatography and high performance liquid chromatography, crystallization, fractional sublimation may be used to isolate diamondoids.

Even after distillation or pyrolysis/distillation, further purification of the material may be desired to provide selected diamondoids for use in the compositions employed in this invention. Such purification techniques include chromatography, crystallization, thermal diffusion techniques, zone refining, progressive recrystallization, size separation, and the like. For instance, in one process, the recovered feedstock is subjected to the following additional procedures: 1) gravity column chromatography using silver nitrate impregnated silica gel; 2) two-column preparative capillary gas chromatography to isolate diamondoids; 3) crystallization.

An alternative process is to use single or multiple column liquid chromatography, including high performance liquid chromatography, to isolate the diamondoids of interest. As above, multiple columns with different selectivities may be used. Further processing using these methods allow for more refined separations which can lead to a substantially pure component.

Detailed methods for processing feedstocks to obtain higher diamondoid compositions are set forth in U.S. Provisional Patent Application No. 60/262,842 filed Jan. 19, 2001; U.S. Provisional Patent Application No. 60/300,148 filed Jun. 21, 2001; and U.S. Provisional Patent Application No. 60/307,063 filed Jul. 20, 2001. These applications are herein incorporated by reference in their entirety.

Unlike larger diamond particulates which are often used as seeds for diamond CVD deposition, diamondoids can be readily derivatized with chemical groups that can act as linkers to chemically bond the diamondoid to a surface. An example is the attachment of diamondoid-thiol derivatives to metal surfaces, e.g. gold. Another is attachment of diamondoids to silicon surfaces via an oxygen bond. A means of attachment of diamondoids to silicon wafers is silylation linking reactions. Silylation reactions have long been used to attach hydrocarbon moieties to silica and glass surfaces. Trimethylsilyl ethers are established agents for derivatizing glass and silica to form non-wetable surfaces. Alkyl silyl ethers are widely used to form derivatives with enhanced thermal stability to aid, e.g., in high-temperature mass spectral analyses as discussed by Denney, R. C., Silylation Reagents for Chromatography. Spec. Chem. 6 (1983). Such layers are thermally stable at CVD operating temperature. One method of attachment would involve forming diamondoid-containing silylating agents that could be reacted with siloxyl moieties on oxidized silicon surfaces. Such methods could employ, e.g., silylating reagents containing specific diamondoids or alkyl diamondoids as one of the alkyl groups on a trialkylhalosilane or other trialkyl silylation reagents. Silylating reactions would involve established base-catalyzed methods. Other suitable chemical bonding methods via a chemical linking groups may also be used.

The diamondoids can also be linked together to form dimers, trimers, etc., and then attached as dimers, trimers, etc. to the substrate by means of a chemical linker. Also, diamondoids can first be attached to the substrate through one kind of linker group, and then bonded together in desired orientation through another kind of linker group, e.g., to make possible homoepitaxy.

Because the quality of CVD diamond grown is a function of the seeding density, diamondoids, being the smallest diamond units possible, ensure the highest possible seeding density and best quality films. Small CVD seed crystals promote effective nucleation and more uniform CVD diamond films with superior mechanical, electronic, (e.g., field emission), optical, and thermal conductivity properties.

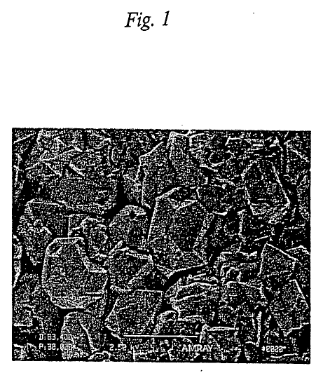

Currently, CVD nucleation is achieved by abrading or scratching a surface (e.g., polished silicon) with fine-grain diamond particulates prior to the CVD process. Iijima, S., Aikawa, Y. & Baba K., in “Growth of diamond particles in chemical vapor deposition.” J. Mater. Res. 6, 1491-1497 (1991), have shown that this abrading technique embeds tiny diamond fragments (tens of nm in size) into the silicon surface. These seeds have various orientations making homoepitaxy impossible. These diamond fragments act as seeds for CVD growth. Iijima et al. (1991) has determined that the highest possible nucleation density achievable with this abrading technique is 10¹⁰ to 10¹¹/cm². Diamondoids are the smallest possible diamond particles, having sizes in the 1 to 2 nm range. The small size of diamondoids makes it possible to increase the nucleation density to 10¹³ to 10¹⁴/cm² a great improvement over nucleation densities possible with previous techniques. Diamondoids can be deposited onto a surface either physically or chemically (as diamondoid derivatives) prior to the CVD process. FIG. 1 shows a CVD diamond crystalline film formed using diamondoid (tetramantane) seed crystals (CVD conditions: 6% 50 Ton, 5 KW, 333H2, SCCM/22 C1-I₄, 700° C., 8 hrs).

Delamination of CVD layers from their substrates is problematic and an impediment to potential CVD diamond applications. Chemically attaching the diamondoids to the substrate as a monolayer will provide an astronomical number (on the order of 10¹³ to 10¹⁴/cm²) of anchor points and will thus mitigate or eliminate the delamination problem. This also improves heat transfer across the interface.

Diamondoids do not need to be physically embedded into a surface like diamond particulate seeds using abrading processes (scratching or ultrasound) that physically damage the surface. Therefore, surface abrasion can be eliminated by chemically attaching diamondoid seed crystals to a surface prior to CVD. Preventing or minimizing surface damage is especially important in applications such as microelectronics and production of Micro Electro-Mechanical Systems (MEMS).

Diamondoids can be chemically attached to surfaces in various patterns. For example, an electronic circuit could be drawn onto metal surfaces with diamondoid-thiols for nanolithography. These patterns can used as is, or used as seeds for patterned diamond CVD growth. In addition, patterned CVD deposition can be accomplished by masking a surface (e.g., polished silicon) so that only specific patterns on that surface are exposed. For example, diamondoid-containing silylating agents can be reacted with siloxyl moieties on the exposed silicon surface, thus forming a dense, predetermined pattern of CVD diamond seed crystals. Once bonding of diamondoids via sily-ether linkages is completed, the mask is removed and diamond is deposited by the high-temperature CVD process. The deposition of CVD diamond in predetermined patterns makes possible a wide range of new microelectronics applications, such as the production of ultra-thin insulating layers with high thermal conductivity, and applications such as the production of MEMS components composed of diamond. Diamond is a highly desirable material for MEMS construction because of its strength, wear resistance, and low coefficient of friction.

In addition to forming patterns, diamondoids can be attached to the substrate in order to induce CVD diamond growth of a particular diamond face. For example, the diamondoid can be anchored to the substrate in order to induce growth along the (111) face, creating an extremely flat diamond surface. Using current methods of seeding (e.g. Russian nanodiamonds) the crystal faces of the seed crystals are randomly orientated. These random orientations cause formation of polycrystalline CVD films. Homoepitaxy is only possible for nucleation using oriented diamond crystal faces By using diamondoid derivatives it is possible to control the orientation of the diamond crystal faces used for CVD diamond nucleation. In order to completely control diamond orientations to make the best homoepitaxial films the diamondoids attached to the surface can be linked to each other to insure the desired result.

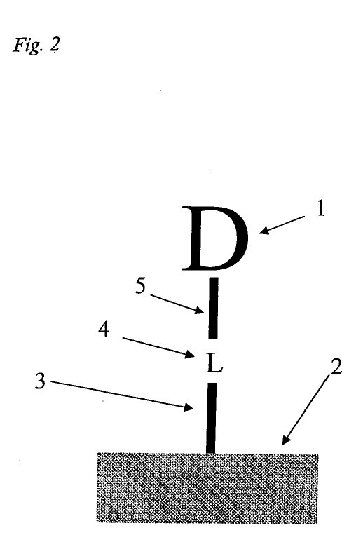

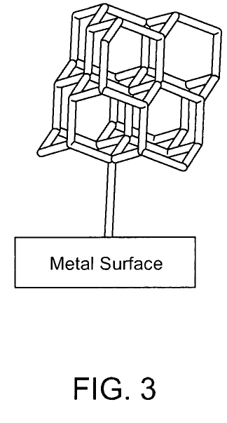

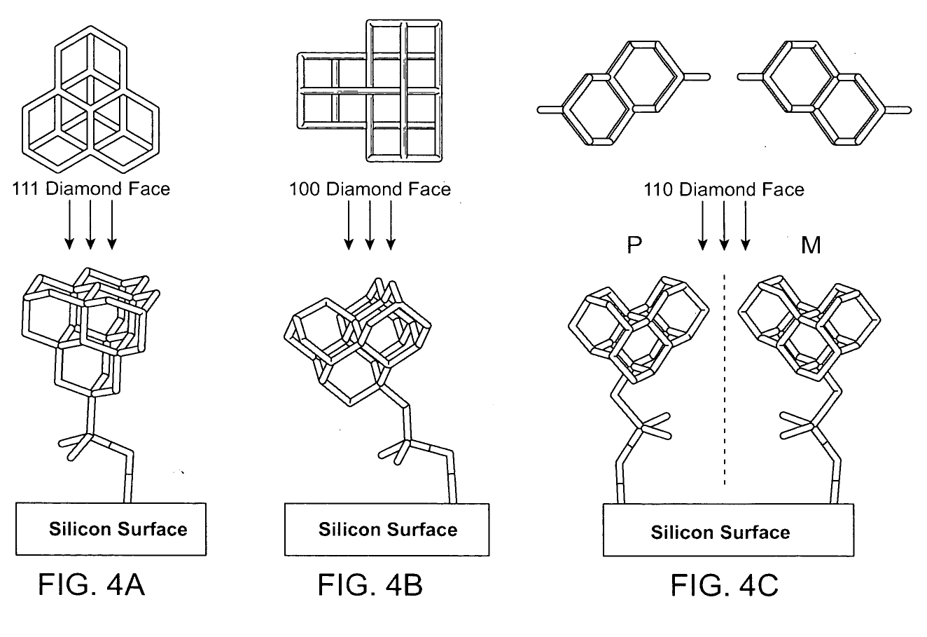

Chemical bonding of diamondoids to surfaces (FIGS. 2 and 3) prior to CVD makes possible predetermined orientation of diamond crystal faces of the seeds. FIG. 4A shows a [1(2,3)4] pentamantane moiety bonded to a siloxyl group on a silicon surface. The [1(2,3)4] pentamantane is bonded to the surface siloxyl via a bridge-head tertiary carbon through an alkyl silyl ether linkage. Bonding the [1(2,3)4] pentamantane to the surface in this fashion exposes its—diamond (111) surface plane for CVD nucleation/diamond deposition.

The relative effectiveness of the {100} and {110} diamond faces toward CVD nucleation could also be applied using other diamondoid structures. FIG. 4B shows a [12(3)4] pentamantane moiety bonded to a siloxyl group on a silicon surface via a bridge-head tertiary carbon through an alkyl silyl ether linkage. Bonding the [12(3)4] pentamantane to the surface in this fashion exposes its (100) surface to CVD reactants. Likewise, FIG. 4C shows [123] tetramantane moieties bonded to a siloxyl group on a silicon surface via a bridge-head tertiary carbons through alkyl silyl ether linkages. Bonding [123] tetramantanes to a surface in this fashion exposes their (110) surfaces. The [123] tetramantanes shown in FIG. 4C offer the unique opportunity to utilize seed-crystal chirality in the nucleation of CVD diamond formation. The [123] tetramantane is a resolvable chiral molecule having primary helicity (it shows both a right- and left-handed primary helical structures).

FIG. 2 shows a diamondoid molecule, 1, bound to a surface acting as oriented seed crystal for CVD diamond nucleation/production. 2 is a surface, for example, a metal, silicon, glass, ceramic, organic polymer, any material that can be bonded to 1, a lower diamondoid, higher diamondoid, heterodiamondoid, or other diamondoid derivative. 1, the diamondoid moiety is bonded to 2 via a linker group (4), that is attached to the surface by bond, 3, and the diamondoid by bond 5. Alternatively, the diamond can be bonded directly to the surface.

FIG. 3 shows an example of a diamondoid, in this case [1231241(2)3] decamantane, bonded to a metal surface, e.g., gold, via a thio sulfur linkage.

FIG. 4 shows diamondoids attached to a silicon surface through a silyl ether bond. FIG. 4A is [1(2,3)4] pentamantane with its (111) face exposed. FIG. 4B is [12(3)4] pentamantane with its (100) face exposed. FIG. 4C is Chiral [123] tetramantane, enantiomer pair with (110) faces exposed.

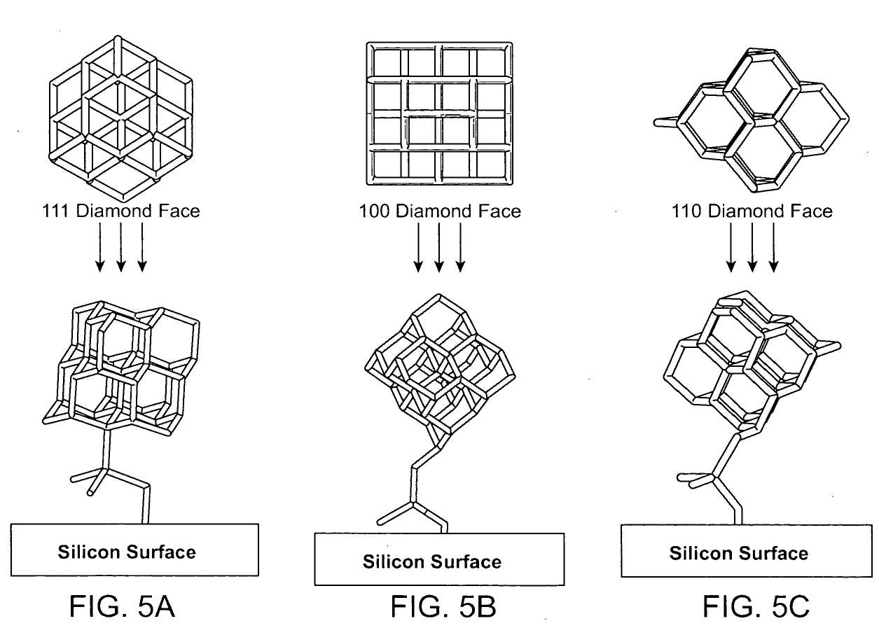

FIG. 5A, 5B, and 5C show how [1231241(2)3] decamantane molecules can be attached to a silicon surface in various ways to exposing specific diamond crystal faces. FIG. 5A shows how binding through a silyl ether linkage could expose a (111) diamond face, FIG. 5B a (100) diamond face, and FIG. 5C the (110) face. In this way, diamondoids could be used to determine both crystal face orientation and crystal size and uniformity of CVD diamond nucleation seeds, thus making possible homoepitaxy. Homoepitaxical diamond growth is needed for production of high-quality diamond materials for microelectronics applications. This can be achieved by linking the diamondoids attached to the surface to each other by using a suitable chemical linker.

Diamondoids are available in a variety of sizes ranging from 1 to 11 diamond crystal cages. This provides the ability to select the precise size of nucleation seeds, an ability not possible with other CVD nucleation methods. In some applications it is desirable to use somewhat larger or smaller seeds to produce diamond layers of appropriate properties and quality.

Diamondoids can be derivatized with nitrogen or boron or other moieties. Incorporation of these derivatives in surface diamondoid seed crystal layers results in CVD diamond films doped with either n-type or p-type elements in the lattice, offering a new way of doping CVD diamonds.

The use of chemical linking techniques may enable the growth of diamond on non-conducting or fragile surfaces. The surfaces are first be coated with diamondoids to create a high density layer of nucleation sites and then a low temperature CVD process is used to grow diamond layer.

Finer and more uniform diamond films may be made by chemically attaching diamondoids to surfaces to form monolayers which could be irradiated to produce a diamond-like-layer without surface heating associated with CVD processing.

Once diamondoids are attached to the substrate as a seed, one can use standard CVD methods. Methane, ethane, ethylene, acetylene and other gaseous carbon sources can be used in standard CVD methods. Hydrogen can be used in the nucleation process as well, together with the carbon source gas, and preferably in combination with an inert gas such as nitrogen or argon.

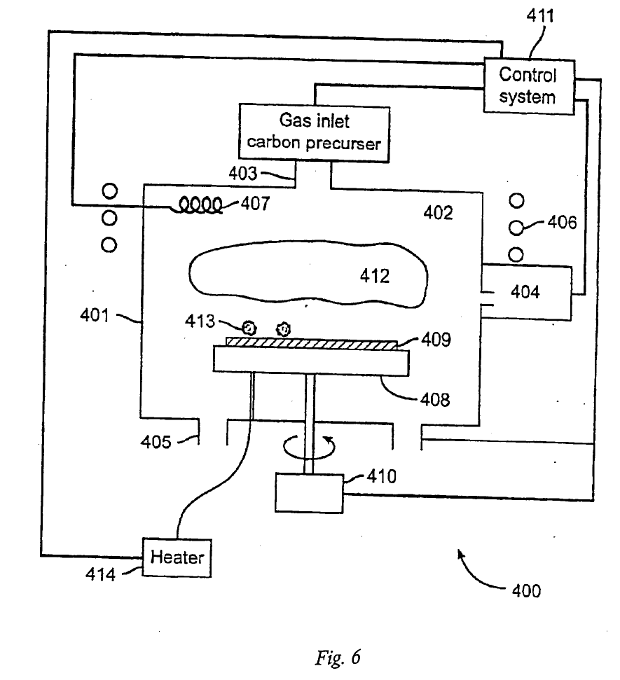

In another embodiment, once the desired diamondoid has been chemically attached to the surface, techniques as described in U.S. Pat. No. 6,783,589 can then be used to sublime diamondoids into the gas phase for CVD. An exemplary reactor to be used is shown generally at 400 in FIG. 6. A reactor 400 comprises reactor walls 401 enclosing a process space 402. A gas inlet tube 403 is used to introduce process gas into the process space 402, the process gas comprising methane, hydrogen, and optionally an inert gas such as argon. A diamondoid subliming or volatilizing device 404, similar to the quartz transpirator discussed above, may be used to volatilize and inject a diamondoid containing gas into the reactor 400. The volatilizer 404 may include a means for introducing a carrier gas such as hydrogen, nitrogen, argon, or an inert gas such as a noble gas other than argon, and it may contain other carbon precursor gases such as methane, ethane, or ethylene.

Consistent with conventional CVD reactors, the reactor 400 may have exhaust outlets 405 for removing process gases from the process space 402; an energy source for coupling energy into process space 402 (and striking a plasma from) process gases contained within process space 402; a filament 407 for converting molecular hydrogen to monoatomic hydrogen; a susceptor 408 onto which a diamondoid containing film 409 is grown; a means 410 for rotating the susceptor 408 for enhancing the Sp³—hybridized uniformity of the diamondoid-containing film 409; and a control system 411 for regulating and controlling the flow of gases through inlet 403, the amount of power coupled from source 406 into the processing space 402; and the amount of diamondoids injected into the processing space 402 the amount of process gases exhausted through exhaust ports 405; the atomization of hydrogen from filament 407; and the means 410 for rotating the susceptor 408. In an exemplary embodiment, the plasma energy source 406 comprises an induction coil such that power is coupled into process gases within processing space 402 to create a plasma 412.

A diamondoid precursor (which may be a triamantane or higher diamondoid) may be injected into reactor 400 according to embodiments of the present invention through the volatilizer 404, which serves to volatilize the diamondoids. A carrier gas such as methane or argon may be used to facilitate transfer of the diamondoids entrained in the carrier gas into the process space 402. The injection of such diamondoids may facilitate growth of a CVD grown diamond film 409 by allowing carbon atoms to be deposited at a rate of about 10 to 100 or more at a time, unlike conventional plasma CVD diamond techniques in which carbons are added to the growing film one atom at a time. Growth rates may be increased by at least two to three times and in some embodiments, growth rates may be increased by at least an order of magnitude.

It may be necessary, in some embodiments, for the injected methane and/or hydrogen gases to “fill in” diamond material between diamondoids, and/or “repair” regions of material that are “trapped” between the aggregates of diamondoids on the surface of the growing film 409. Hydrogen participates in the synthesis of diamond by PECVD techniques by stabilizing the sp³ bond character of the growing diamond surface. As discussed in the reference cited above, A. Erdemir et al. teach that hydrogen also controls the size of the initial nuclei, dissolution of carbon and generation of condensable carbon radicals in the gas phase, abstraction of hydrogen from hydrocarbons attached to the surface of the growing diamond film, production of vacant sites where sp³ bonded carbon precursors may be inserted. Hydrogen etches most of the double or sp² bonded carbon from the surface of the growing diamond film, and thus hinders the formation of graphitic and/or amorphous carbon. Hydrogen also etches away smaller diamond grains and suppresses nucleation. Consequently, CVD grown diamond films with sufficient hydrogen present leads to diamond coatings having primarily large grains with highly faceted surfaces. Such films may exhibit the surface roughness of about 10 percent of the film thickness. In the present embodiment, it may not be as necessary to stabilize the surface of the film, since carbons on the exterior of a deposited diamondoid are already Sp³ stabilized.

Diamondoids may act as carbon precursors for a CVD diamond film, meaning that each of the carbons of the diamondoids injected into processing space 402 are added to the diamond film in a substantially intact form. In addition to this role, diamondoids 413 injected into the reactor 400 from the volatilizer 404 may serve merely to nucleate a CVD diamond film grown according to conventional techniques. In such a case, the diamondoids 413 are entrained in a carrier gas, the latter which may comprise methane, hydrogen, and/or argon, and injected into the reactor 400 at the beginning of a deposition process to nucleate a diamond film that will grow from methane as a carbon precursor (and not diamondoid) in subsequent steps. In some embodiments, the selection of the particular isomer of a particular diamondoid may facilitate the growth of a diamond film having a desired crystalline orientation that may have been difficult to achieve under conventional circumstances. Alternatively, the introduction of a diamondoid nucleating agent into reactor 400 from volatilizer 404 may be used to facilitate an ultracrystalline morphology into the growing film for the purposes discussed above.

The weight of diamondoids and substituted diamondoids, as a function of the total weight of the CVD film (where the weight of the diamondoid functional groups are included in the diamondoid portion), may in one embodiment range from about 1 to 99.9 percent by weight. In another embodiment, the content of diamondoids and substituted diamondoids is about 10 to 99 percent by weight. In another embodiment, the proportion of diamondoids and substituted diamondoids in the CVD film relative to the total weight of the film is about 25 to 95 percent by weight.

While the present invention has been described with reference to specific embodiments, this application is intended to cover those various changes and substitutions that may be made by those of ordinary skill in the art without departing from the spirit and scope of the appended claims.

What is claimed is:

1. A method of nucleating the growth of a diamond film, comprising providing a substrate upon which the film is to be nucleated, wherein at least one diamondoid is chemically attached to the substrate.

2. The method of claim 1, wherein the diamondoid is a lower diamondoid.

3. The method of claim 2, wherein the lower diamondoid is selected from the group consisting of adamantane, diamantane and traimantane.

4. The method of claim 1, wherein the diamondoid is a higher diamondoid.

5. The method of claim 4, wherein the higher diamondoid is selected from the group consisting of tetramantane, pentamantane, hexamantane, heptamantane, octamantane, nonamantane, decamantane, and undecamantane.

6. The method of claim 1, wherein the diamondoid is derivatized with nitrogen or boron.

7. A method of nucleating the growth of a diamond film, the method comprising the steps of:
a) providing a reactor having an enclosed process space;
b) positioning a substrate within the process space and chemically attaching a diamondoid to said substrate;
c) introducing a process gas into the process space; and,
d) coupling energy into the process space from an energy source.

8. The method of claim 7, wherein the method further comprises injecting at least one higher diamondoid into the process space, wherein the at least one higher diamondoid nucleates the growth of the diamond film on the substrate.

9. The method of claim 7, wherein the method further comprises injecting at least diamondoid into the process space, wherein the at least one higher diamondoid is derivatized with nitrogen or boron.

10. The method of claim 7, wherein the method further comprises injecting at least one lower diamondoid into the process space, wherein the at least one lower diamondoid nucleates the growth of the diamond film on the substrate.

11. The method of claim 7, wherein the reactor is configured to carry out a chemical vapor deposition (CVD) technique.

12. The method of claim 11, wherein the chemical vapor deposition technique is a plasma enhanced chemical vapor deposition (PECVD) technique.

13. The method of claim 8, wherein the at least one higher diamondoid is a substituted higher diamondoid.

14. The method of claim 7, wherein the nucleation is independent of the nature of the substrate.

15. The method of claim 7, wherein the substrate is a carbide forming substrate.

16. The method of claim 15, wherein the substrate is selected from the group consisting of Si and Mo.

17. The method of claim 7, wherein the substrate is a non-carbide forming substrate.

18. The method of claim 17, wherein the substrate is selected from the group consisting of Ni and Pt.

19. The method of claim 7, wherein the process gas comprises methane and hydrogen.

20. The method of claim 19, wherein the process gas further includes an inert gas.

21. The method of claim 20, wherein the inert gas is argon.

22. The method of claim 7, wherein the energy source comprises an induction coil such that the power coupled into the process space generates a plasma.

23. The method of claim 19, further including the step of converting the hydrogen within the process space to monoatomic hydrogen.

24. The method of claim 8, wherein the injecting step comprises volatilizing the at least one higher diamondoid by heating such that it sublimes into the gas phase.

25. The method of claim 24, wherein the injecting step includes entrainment of the sublimed higher diamondoid in a carrier gas which is introduced into the process chamber.

26. The method of claim 25, wherein the carrier gas is at least one gas selected from the group consisting of hydrogen, nitrogen, an inert gas, and a carbon precursor gas.

27. The method of claim 26, wherein the inert gas is a noble gas, and wherein the carbon precursor gas is at least one gas selected from the group consisting of methane, ethane, and ethylene.

28. The method of claim 7, wherein the nucleation density is at least 10¹³ cm⁻².

29. The method of claim 8, wherein the injecting of the at least one higher diamondoid increases the growth rate of the diamond film by a factor of at least two to three times.

30. The method of claim 10, wherein the injecting of the at least one lower diamondoid increases the growth rate of the diamond film by a factor of at least two to three times.

31. The method of claim 8, further including the step of selecting a particular higher diamondoid to facilitate the growth of a diamond film having a desired crystalline orientation.

32. The method of claim 7, wherein the substrate is rotated during at least a part of the growth of the diamond film.

33. A diamond film nucleated on a substrate having a diamondoid chemically attached to said substrate prior to nucleation.

34. The diamond film of the claim 33, wherein the diamondoid is derivatized with nitrogen or boron.

35. The diamond film of claim 33, wherein the diamondoid is a higher diamondoid.

36. The diamond film of claim 33, wherein the diamondoid is a lower diamondoid.

37. A diamond film nucleated by the steps comprising:
a) providing a reactor having an enclosed process space;
b) positioning a substrate within the process space, with the substrate having chemically attached to it a diamondoid;
c) introducing a process gas into the process space; and
d) coupling energy into the process space from an energy source.

38. The diamond film of claim 37, wherein the diamond film is an ultrananocrystalline film.

39. The diamond film of claim 38, wherein the ultrananocrystalline film has a microstructure comprising a three to five nanometer crystallite size.

40. The diamond film of the claim 37, wherein the diamondoid is derivatized with nitrogen or boron.

41. The diamond film of claim 37, wherein the diamondoid is selected from the group consisting of adamantane, diamantane, triamantane, tetramantane, pentamantane, hexamantane, heptamantane, octamantane, nonamantane, decamantane, and undecamantane.

42. The diamond film of claim 37, wherein the higher diamondoid is selected from the group consisting of adamantane, diamantane, triamantane, tetramantane, pentamantane, hexamantane, heptamantane, octamantane, nonamantane, decamantane, and undecamantane.
